(19) United States
(12) Patent Application Publication
(10) Pub. No.: US 2025/0149465 A1
(43) Pub. Date: May 8, 2025

(54) CRACKSTOP BARRIER ARCHITECTURE FOR HYBRID BONDED SEMICONDUCTOR PACKAGES

(71) Applicant: International Business Machines Corporation, Armonk, NY (US)

(72) Inventors: Nicholas Alexander POLOMOFF, Hopewell Junction, NY (US); RAVI K. BONAM, Albany, NY (US); Huai Huang, Clifton Park, NY (US)

(21) Appl. No.: 18/504,142

(22) Filed: Nov. 7, 2023

(51) Int. Cl. H01L 23/00

(52) U.S. Cl. CPC H01L 23/562; H01L 24/08; H01L 24/80; H01L 2224/08145; H01L 2224/80895; H01L 2224/80896

(57) ABSTRACT

A semiconductor structure includes an upper semiconductor build having an upper crackstop structure along its periphery, an upper semiconductor build insulator layer, and a plurality of upper semiconductor build electrical contact bonding pads within the insulator layer. The upper semiconductor build crackstop structure includes first and second upper semiconductor build crackstop portions ending in first and second upper semiconductor build non electrical contact bonding pads within the insulator layer. A lower semiconductor build is generally similar to the upper semiconductor build, and the two builds are connected by a hybrid bond joining interface including metal-to-metal bonding of the bonding pads, and dielectric bonding of the insulator layers. A continuous structural element is located between the first and second upper semiconductor build crackstop portions and corresponding first and second lower semiconductor build crackstop portions, passing through the hybrid bond joining interface and sealing around the semiconductor build peripheries.

### BACKGROUND

The present invention relates generally to the electrical, electronic and computer arts and, more particularly, to joining two semiconductor builds such as chips, dies, wafers, interposers, or combinations thereof together and, further, to structures that prevent moisture ingress as well as block or minimize external or internal crack growth or propagation originating primarily from dicing wafers and delamination and warpage from chip package interaction (CPI) related issues or threats, and the like.

In hybrid bonding, a permanent bond combines a dielectric bond (e.g., SiOₓ) with embedded metal (e.g., Cu) to form interconnections. Two semiconductor builds are joined (e.g., two individual wafers that are built separately). They require a “pristine” surface (smooth and flat, possibly with some recesses), more so than traditional chemical-mechanical planarization (CMP). The two builds are purposely designed to align. The term “hybrid” refers to the presence of both copper and dielectric. A bond that uses dielectric alone is referred to as fusion bonding (oxide to oxide). Hybrid bonding uses metal to metal connections for the copper. The two builds are brought together and a small heat treatment/annealing process is carried out. The oxides bond together and the metals “anneal,” or almost melt, together, thus fusing the interface into a single bonded part (in some instances, seamlessly; i.e., the interface line disappears).

In semiconductor processing, dicing (a violent mechanical process) potentially creates many cracks that can eventually cause catastrophic failure of the semiconductor device build. Some prior art techniques require dicing both before and after hybrid bonding, thereby potentially creating latent defects and multiple opportunities for crack propagation during thermal cycling, application of mechanical forces, and the like, which can manifest into cracks, delamination, pulling the dies apart, and so on.

In current approaches to hybrid bonding, each build has a crackstop (typically, a barrier to stop cracks and moisture); this is needed during construction. Current techniques do not have the capability to stop moisture or cracks in the join area (between the builds). That is to say, current hybrid bonding techniques have a gap at the junction between the two crackstops. In current techniques, cracks from earlier processing (i.e., pre-join) can bypass the join area or a new crack can form post join from mechanical vibration/CPI/heat/thermal cycling, or the like. A crack can potentially break electrical connections, or even propagate into the device region, potentially leading to failure. That is to say, in current hybrid bonding techniques, the gap opening can be leveraged by cracks to separate the two bonded pieces, or as an access entry point from which they can bypass the crackstop structures and potentially dive down into the stack within the prime active region, resulting in die failure.

Furthermore, when creating the metal pads used in hybrid bonding to join the other metal features, having a large metal structure like the crack stop nearby will tend to throw off the uniformity of the top surface.

### BRIEF SUMMARY

Principles of the invention provide techniques for a crackstop barrier architecture for hybrid bonded semiconductor packages. In one aspect, an exemplary semiconductor structure includes an upper semiconductor build having an upper crackstop structure along an upper semiconductor build periphery, an upper semiconductor build insulator layer, and a plurality of upper semiconductor build electrical contact bonding pads within the upper semiconductor build insulator layer. The upper semiconductor build crackstop structure includes first and second upper semiconductor build crackstop portions ending in first and second upper semiconductor build non electrical contact bonding pads within the upper semiconductor build insulator layer. Also included is a lower semiconductor build having a lower crackstop structure along a lower semiconductor build periphery, a lower semiconductor build insulator layer, and a plurality of lower semiconductor build electrical contact bonding pads within the lower semiconductor build insulator layer. The lower semiconductor build crackstop structure includes first and second lower semiconductor build crackstop portions ending in first and second lower semiconductor build non electrical contact bonding pads within the lower semiconductor build insulator layer. The upper and lower semiconductor builds are connected by a hybrid bond joining interface including metal-to-metal bonding of the plurality of upper semiconductor build electrical contact bonding pads with the plurality of lower semiconductor build electrical contact bonding pads, metal-to-metal bonding of the first and second upper semiconductor build non electrical contact bonding pads with the first and second lower semiconductor build non electrical contact bonding pads, and dielectric bonding of the upper semiconductor build insulator layer with the lower semiconductor build insulator layer. A continuous structural element is located between the first and second upper semiconductor build crackstop portions and the first and second lower semiconductor build crackstop portions, passing through the hybrid bond joining interface and sealing around the upper and lower semiconductor build peripheries.

In another aspect, another exemplary semiconductor structure includes an upper composite semiconductor build and a lower composite semiconductor build. Each composite semiconductor build includes an upper semiconductor build and a lower semiconductor build, configured similar to what has just been described, and fastened together by hybrid bonding and with a peripheral monolith. A “grand” continuous structural element passes through the upper and lower composite semiconductor builds and seals around an overall periphery of the final structure. The upper and lower composite semiconductor builds are in turn joined by a composite bond.

In still another aspect, an exemplary method for joining two semiconductor builds includes providing an upper semiconductor build and a lower semiconductor build. The upper semiconductor build has an upper crackstop structure along an upper semiconductor build periphery, an upper semiconductor build insulator layer, and a plurality of upper semiconductor build electrical contact bonding pads within the upper semiconductor build insulator layer. The upper semiconductor build crackstop structure includes first and second upper semiconductor build crackstop portions ending in first and second upper semiconductor build non electrical contact bonding pads within the upper semiconductor build insulator layer. The lower semiconductor build has a lower crackstop structure along a lower semiconductor build periphery, a lower semiconductor build insulator layer, and a plurality of lower semiconductor build electrical contact bonding pads within the lower semiconductor build insulator layer. The lower semiconductor build crackstop structure includes first and second lower semiconductor build crackstop portions ending in first and second lower semiconductor build non electrical contact bonding pads within the lower semiconductor build insulator layer. A further step includes connecting the upper and lower semiconductor builds by a hybrid bonding including metal-to-metal bonding of the plurality of upper semiconductor build electrical contact bonding pads with the plurality of lower semiconductor build electrical contact bonding pads, metal-to-metal bonding of the first and second upper semiconductor build non electrical contact bonding pads with the first and second lower semiconductor build non electrical contact bonding pads, and dielectric bonding of the upper semiconductor build insulator layer with the lower semiconductor build insulator layer. Still further steps include opening a trench between the first and second upper semiconductor build crackstop portions and the first and second lower semiconductor build crackstop portions, passing through a hybrid bond joining interface and around the upper and lower semiconductor build peripheries; and depositing material in the trench to form a continuous structural element located between the first and second upper semiconductor build crackstop portions and the first and second lower semiconductor build crackstop portions, passing through the hybrid bond joining interface and sealing around the upper and lower semiconductor build peripheries.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments provide enhanced survivability of hybrid joined semiconductor devices from CPI related threats (e.g., thermal cycling, external mechanical forces such as vibration, bending, warping, and bowing of the semiconductor build due to various stresses and strains and moisture ingress).

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-6 show steps in an exemplary process flow, according to an aspect of the invention;

FIG. 7 shows a detailed view of a portion of a structure, according to an aspect of the invention;

FIG. 8 shows a simplified three-dimensional view of an exemplary structure, according to an aspect of the invention;

FIG. 9 shows a top down view of the structure of FIG. 8, looking in direction IX, according to an aspect of the invention;

FIG. 10 shows a cross-sectional view of the structure of FIG. 8, looking in direction X-X, according to an aspect of the invention;

FIG. 11 shows a detailed cross-sectional view of an exemplary structure, according to an aspect of the invention;

FIG. 12 shows a first detailed three-dimensional view of the structure of FIG. 11, according to an aspect of the invention;

FIG. 13 shows a second detailed three-dimensional view of the structure of FIG. 11, according to an aspect of the invention;

FIG. 14 shows a top-down view of one die edge region of a structure in accordance with an aspect of the invention;

FIG. 15 shows a cross-sectional view of the die edge region in accordance with an aspect of the invention;

FIG. 16 shows a top-down macroscopic view of the structure with the die edge region in accordance with an aspect of the invention;

FIGS. 17-24 show steps in an alternative exemplary process flow, according to an aspect of the invention;

FIGS. 24-26 show steps in yet another alternative exemplary process flow, according to yet another aspect of the invention; and

FIGS. 27 and 28 depict variant hybrid bonding stacking configurations, according to aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

One or more embodiments provide a crack stop on each individual build, analogous to scaffolding. One or more embodiments incorporate the discrete, discontinuous pads such as are used for the electrical connections, for adhesion, without harming the surface. Once assembled and bonded, one or more embodiments add a TSV-like (TSV=through-silicon-via) copper monolith that molds to the scaffolding on the two individual joined builds; essentially, two crack stops with a third that unifies them (and also provides a moisture barrier).

One or more embodiments provide a continuous seamless metal barrier that surrounds the periphery of an active device prime region. In one or more embodiments, the structure is built through the entirety of the back end of line (BEOL) of a dielectric stack build of each respective semiconductor device or other semiconductor build that has been joined together. For example, the structure can anchor into the base substrate. In one or more embodiments, the structure can align and connect to a variety of predesigned/premade landing regions within each respective BEOL stack on a predesigned crackstop scaffolding that when combined forms a unified crackstop barrier structure.

Indeed, one or more embodiments provide a “hybrid” crackstop structure by a novel arrangement of traditional semiconductor build elements that form a preliminary crack stopping hermetic scaffolding for each individual die respectively-which then has a seamless copper (or other suitable material) monolith ring integrated into its architecture, which bridges and hermetically seals the joining interface between the adjoined dies.

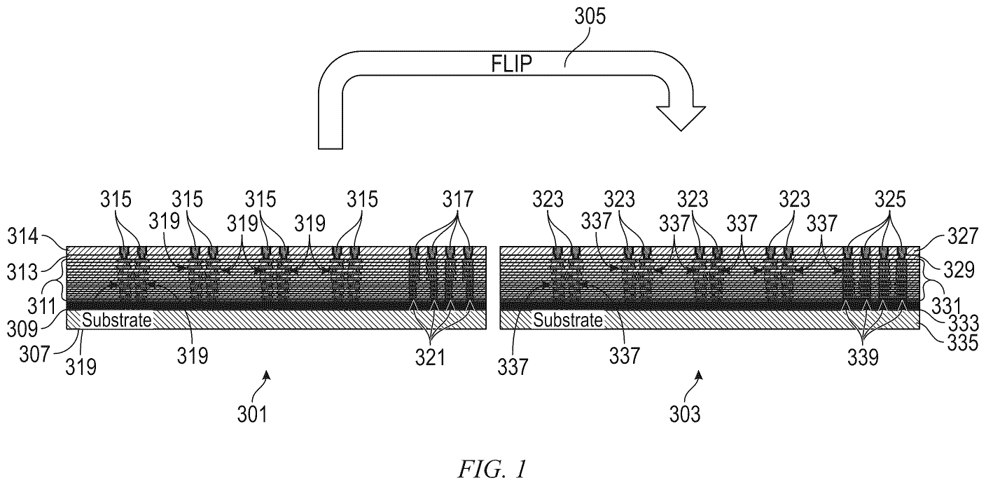

Referring now to FIG. 1, consider an exemplary process flow, according to an aspect of the invention. Note the first semiconductor build 301 and the second semiconductor build 303. First semiconductor build 301 includes substrate 307, device layer 309 (e.g., complementary metal-oxide semiconductor (CMOS) field effect transistors (FETs)) formed on the substrate 307, and BEOL wiring layer 311. The BEOL wiring layer includes metal layers (e.g. copper) and metal vias (e.g., copper) that connect the terminals of the devices in the device layer to the metal pads 315 used in hybrid bonding, and are separated by insulator material (connections are designated as 319). Pads 315 are located in insulation layers 313, 314 outward of the BEOL wiring layer 311. The skilled person will be familiar with the components of the first semiconductor build 301 described thus far. In addition to these conventional elements, first semiconductor build 301 includes scaffold structures 321 with corresponding adhesion pads 317 that are similar to the metal pads 315, and are discussed further below.

Second semiconductor build 303 includes substrate 335, device layer 333 (e.g., complementary metal-oxide semiconductor (CMOS) field effect transistors (FETs)) formed on the substrate 335, and BEOL wiring layer 331. The BEOL wiring layer includes metal layers (e.g. copper) and metal vias (e.g., copper) that connect the terminals of the devices in the device layer to the metal pads 323 used in hybrid bonding, and are separated by insulator material (connections are designated as 337). Pads 323 are located in insulation layers 327, 329 outward of the BEOL wiring layers of 331. The skilled person will be familiar with the components of the second semiconductor build 303 described thus far. In addition to these conventional elements, second semiconductor build 303 includes scaffold structures 339 with corresponding adhesion pads 325 that are similar to the metal pads 323. In one or more embodiments, elements 315, 317, 323, and 325 have similar dimensions, as discussed further below.

In a step of the process flow illustrated in FIG. 1, first semiconductor build 301 is flipped over and brought adjacent to second semiconductor build 303 with pads 317 aligned with pads 325 and pads 315 aligned with pads 323. The flipping is suggested by arrow 305 but in this particular example is not a simple 180 degree flip as the pads are aligned as described (other embodiments could have a mirrored layout such that only a simple 180 degree flip was needed).

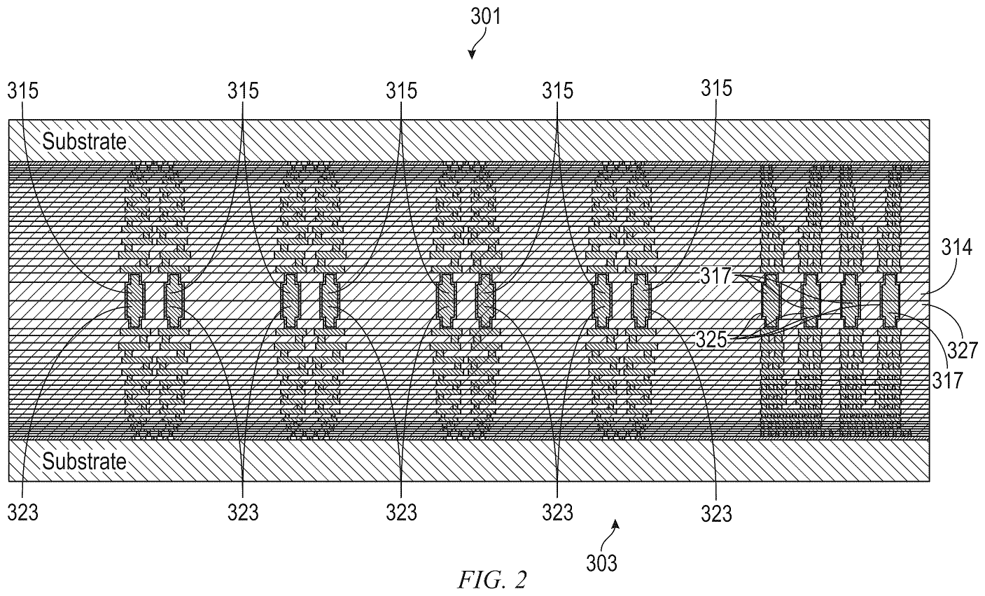

FIG. 2 shows the flipped first semiconductor build 301 and second semiconductor build 303 after hybrid bonding; i.e., the oxides 314, 327 bond together, the metals 315 “anneal” to the metals 323, and the metals 317 “anneal” to the metals 325.

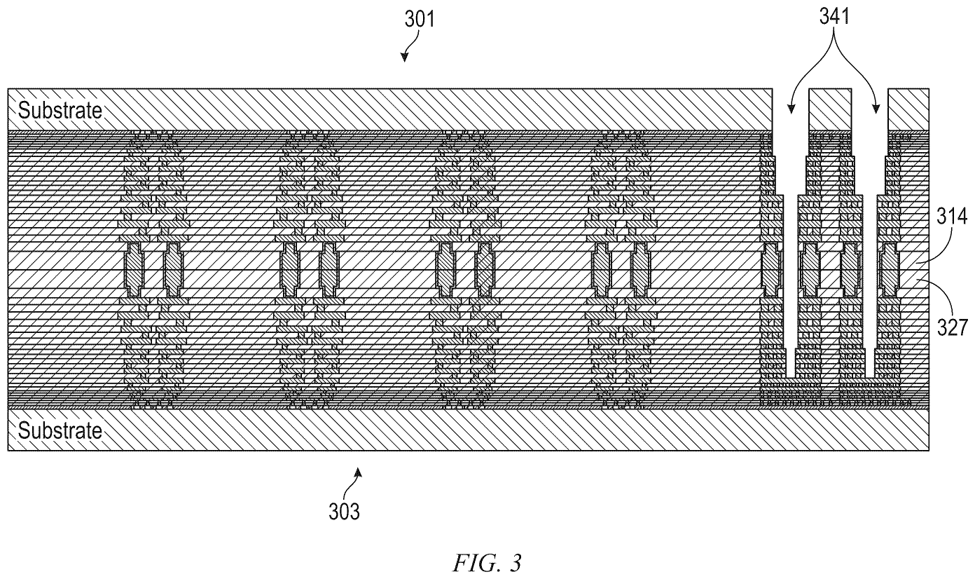

FIG. 3 shows the bonded structure of FIG. 2 after forming openings 341 for monoliths to be subsequently formed; for example, using etching such as reactive ion etching (RIE).

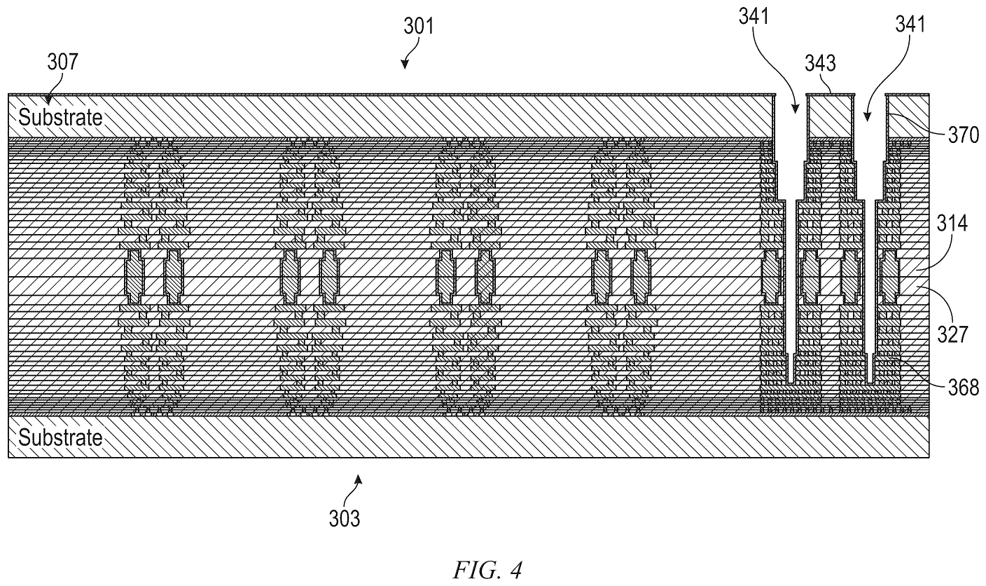

FIG. 4 shows the bonded structure of FIG. 3 after depositing seed liner 343 in the openings 341 as well as the outer surface of substrate 307. Any suitable liner stack can be employed; the skilled artisan is familiar with seed liners that can be applied before metallization of TSVs, such as Ta/TaN, TiW, TiN, CuMn, and the like.

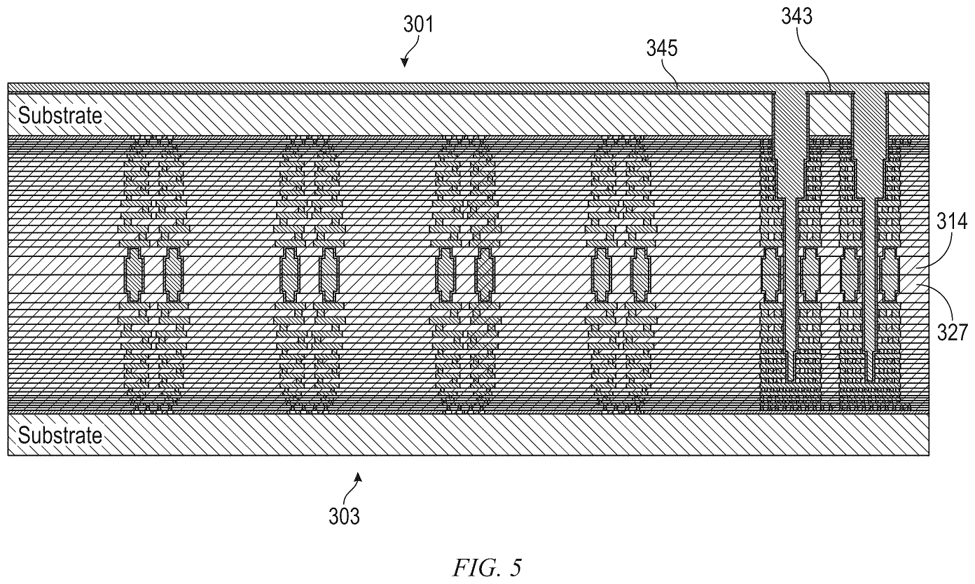

FIG. 5 shows the structure of FIG. 4 after metallizing with metal 345 over the seed liner 343, thus filling the openings 341 (numbered in FIG. 4) with metal.

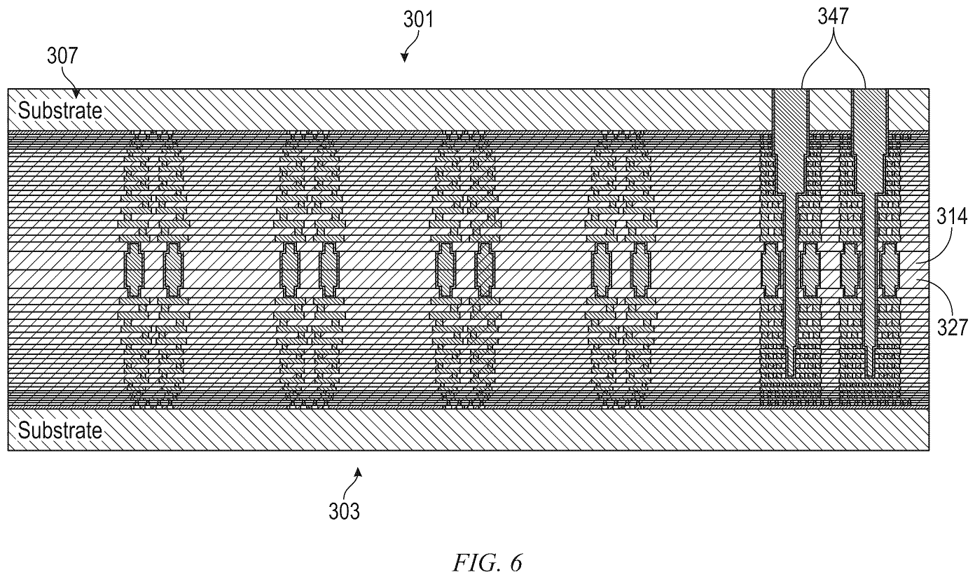

FIG. 6 shows the structure of FIG. 5 after performing CMP to remove the metal overburden 345 and seed liner 343 from the outer surface of the substrate 307, leaving monoliths 347 in the openings 341 (numbered in FIG. 4). It is worth noting that the monolith 347 can be copper or other metal, but does not necessarily need to be copper or other metal; for example, it can be made of TEOS (Tetraethyl orthosilicate, formally named tetraethoxysilane) or other suitable oxide, filled with hermitic robust material having moisture sealing and crack stopping properties, or the like. Other exemplary materials for monolith 347 include other metals such as aluminum or other oxides such as SiN or SiCN.

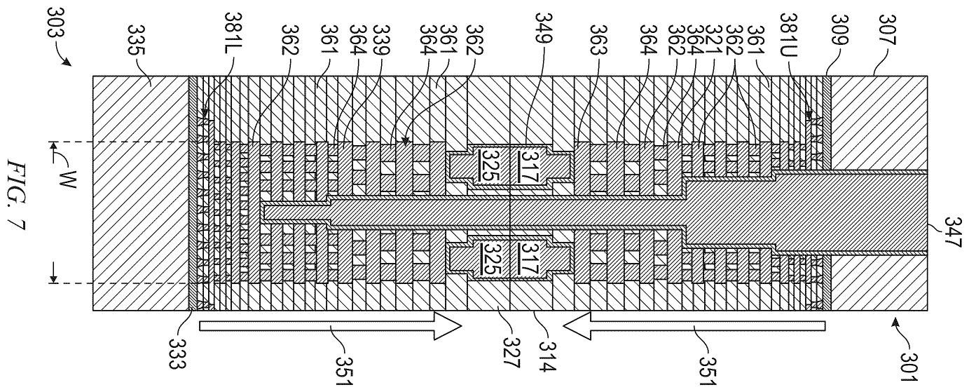

FIG. 7 shows a detailed view of scaffold structure 321 with corresponding adhesion pads 317, scaffold structure 339 with corresponding adhesion pads 325, and monolith 347 such as were shown in FIG. 6. Note the hybrid bond interface 349. Arrows 351 indicate that the thickness of the BEOL dielectric layers 361 and the size and pitch of the metal features (horizontal metal plates/bars/lines 362 and continuous vias 364) increases when moving from the substrates 307, 335 towards the hybrid bond interface 349. It will be appreciated that active devices in the device layers 309, 333 typically include brittle material such as extremely low-k dielectric (ELK), ultra-low-k dielectric (ULK), and low-k dielectric (Low K); the terms ELK, ULK, and Low K are not mere relative terms but have an established meaning to the skilled person in the field of semiconductor fabrication (k stands for dielectric constant). Hybrid bond interface 349 can include, for example, TEOS/SiCN.

Scaffold structures 321, 339 can be made using metal features (horizontal metal plates/bars/lines 362 and continuous vias 364) with traditional sizes for each respective BEOL dielectric layer 361. The width, W, in FIG. 7 of the scaffolding can range, for example, between 2-10 μm. It should be sized to accommodate the cavity for the monolith 347. For example, a 1 μm monolith could have a W=2 μm scaffold. The internal space 341 inside of the scaffolding can be 1-5 μm wide and have a staggered stair case appearance (for example, 1 μm at the bottom narrowest part 368 and 5 μm at the top widest part 370). As seen in FIG. 7, the scaffolding is a series of horizontal metal plates/bars/lines 362 in metallization layers connected by continuous vias 364. Note the optional upper and lower bumper portions 381U, 381L, which are slightly wider than the scaffold; given the teachings herein, the skilled artisan can adapt known structures used, for example, in connection with crack trapping and arrest in thin film structures to implement upper and lower bumper portions 381U, 381L.

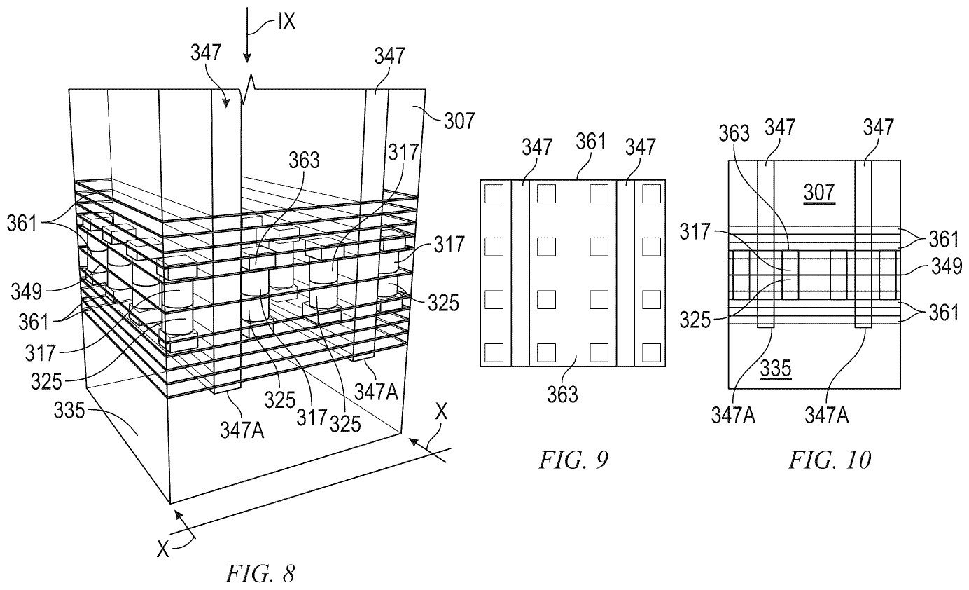

As noted above, in one or more embodiments, bonding pads 315, 317, 323, and 325 have similar dimensions. The bonding pads can, for example, be made of copper with a seeding liner such as Ta/TaN, Cu/Mn, or the like. The bonding pads can be circular in a top plan view (best seen in FIG. 8) and can range from 0.5-4 μm in diameter. As seen in FIG. 7, the larger diameter is seen where the pads touch and bond. In one or more embodiments, bonding pads 315, 317, 323, and 325 are substantially identical (e.g., diameter is within plus or minus 10% of each other); in some cases, identical within process limits. This is advantageous because, in hybrid bonding, if large features are located next to small features, they will behave differently during CMP. Thus, in one or more embodiments, bonding pads 315, 323 for the active area and bonding pads 317, 325 for the crack stop have substantially the same size. Substrates 307, 335 can be silicon. The device layers 309, 333 can have epitaxially grown source-drain regions, channels, gates, contacts, and other known device (e.g., field effect transistor (FET)) structures and materials. The BEOL insulation layers 361 next to the scaffold can be conventional dielectric layers as used in wiring layers. Layers 313, 314, 329, 327 can be TeOS or SiCN or the like.

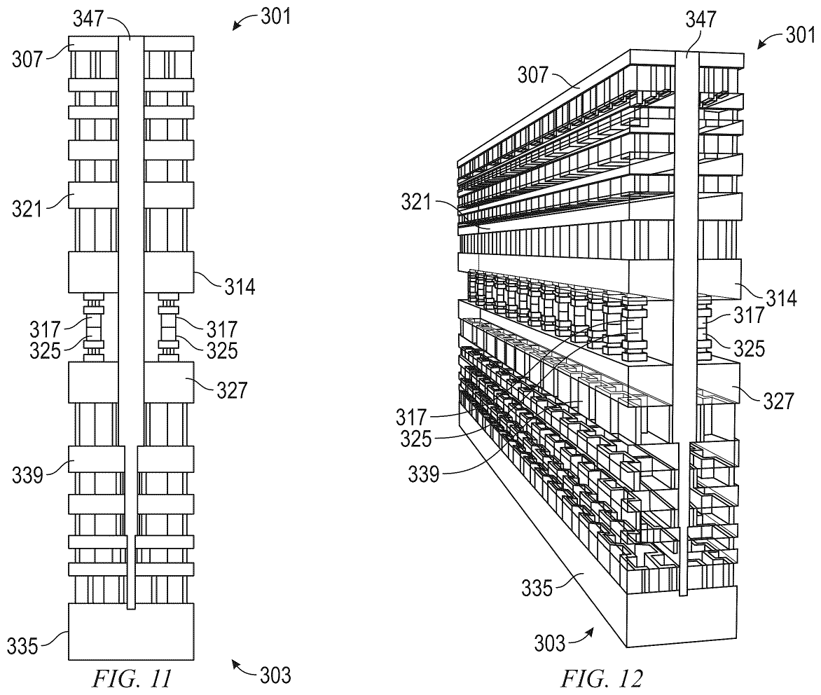

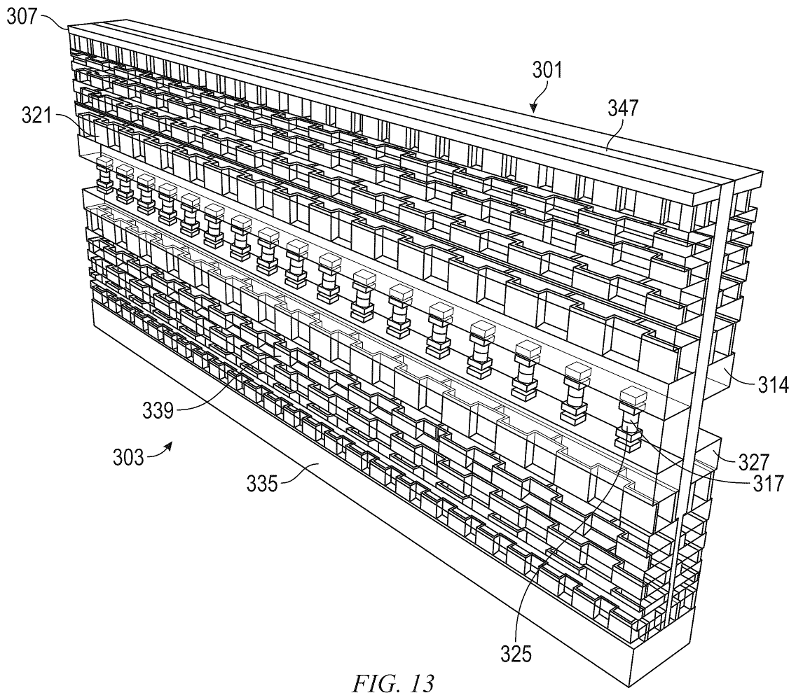

FIGS. 8, 9, and 10 respectively show a simplified three-dimensional view of an exemplary structure, a top down view looking in direction IX, and a cross-sectional view looking in direction X-X. The scaffolding is omitted for clarity. Note the anchoring into the base substrate 335 as seen at 347A. Elements 347 create a continuous through substrate copper (or other material, as discussed) monolith wall that bridges across a die-to-die hybrid bonded interface and is anchored into the base die. The anchoring into the base substrate shown at 347A creates an electrical ground to the substrate (guard ring). Note the BEOL insulation (dielectric) layers 361. Elements 363 are square metal portions on top of pads 317 and beneath pads 325.

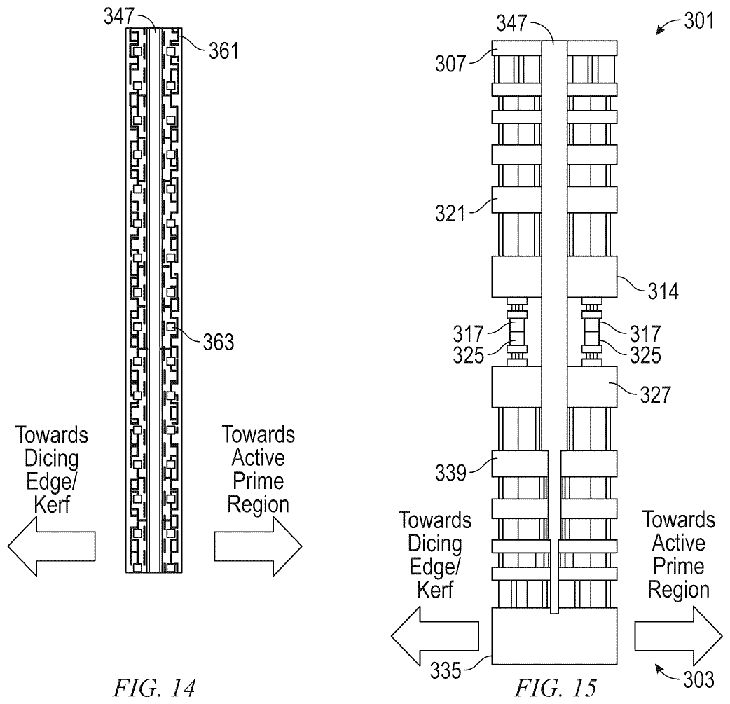

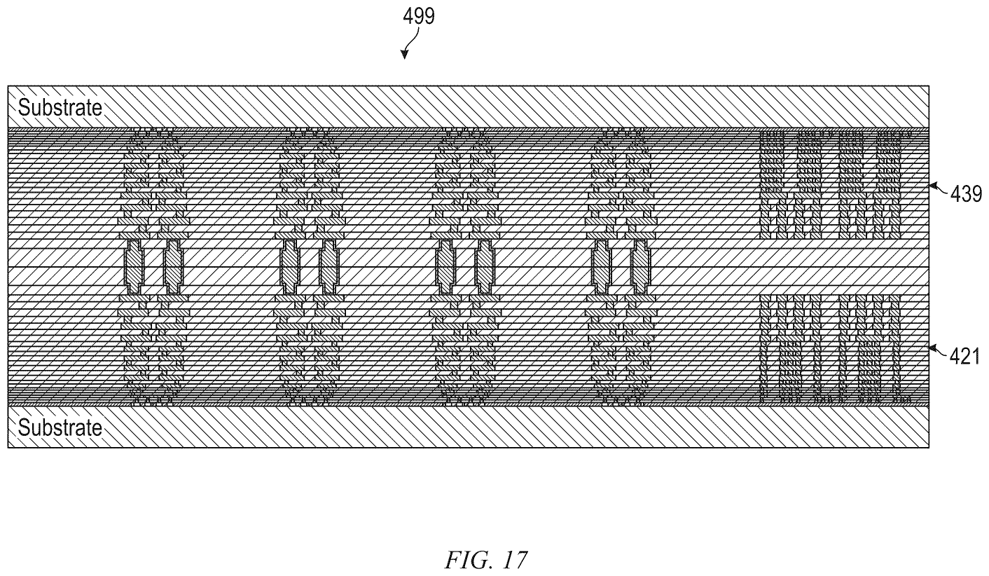

FIGS. 11, 12, and 13 respectively show a detailed cross-sectional view, a first detailed three-dimensional view, and a second detailed three-dimensional view of an exemplary structure, including the scaffolding. The device layer is omitted because the crackstop structures are located at the periphery of the die away from the active regions.

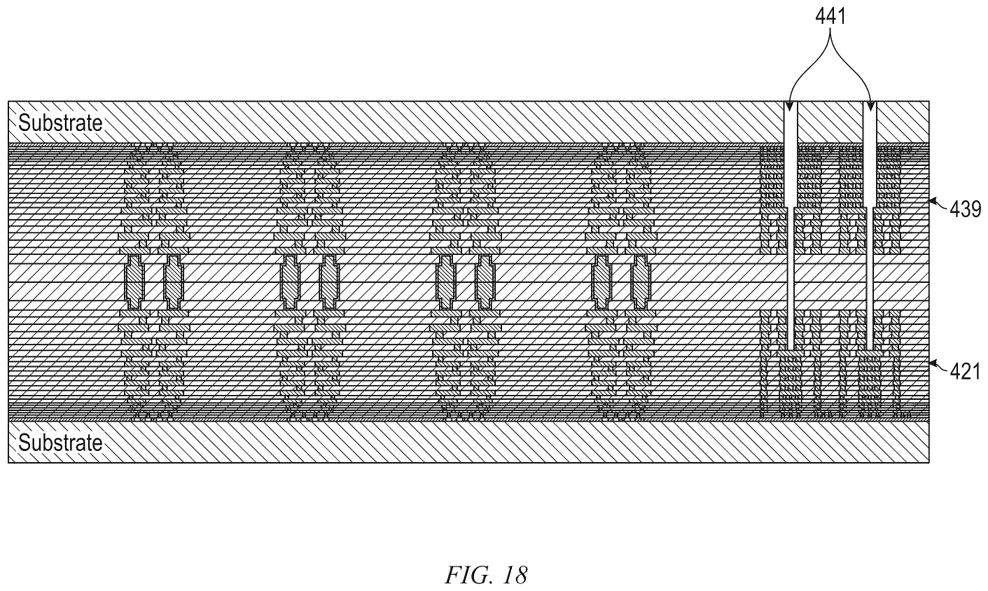

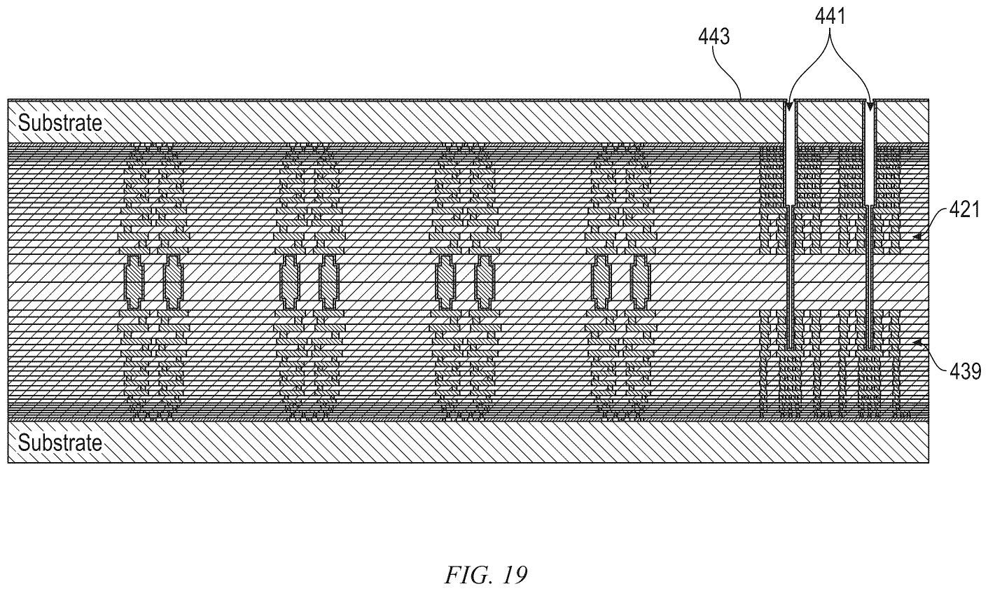

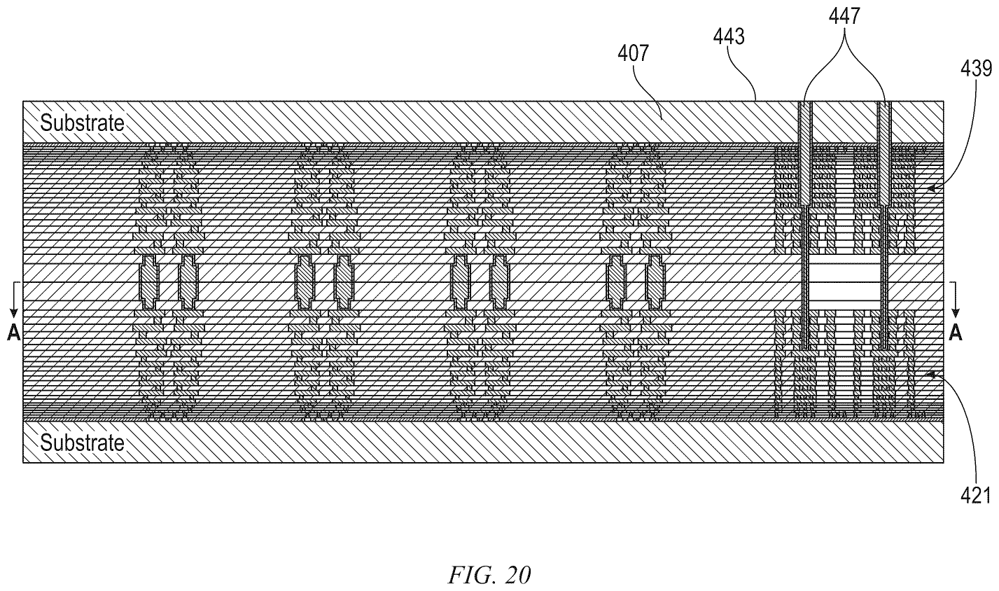

FIGS. 14, 15, and 16 respectively show a top-down view of one die edge region (369 in FIG. 16), a cross-sectional view of one die edge region (369 in FIG. 16), and a top-down macroscopic view showing a structure in accordance with an aspect of the invention surrounding an entire die. FIG. 15 is similar to FIG. 11, also showing the exemplary orientation with respect to FIG. 16. In FIG. 16, note the active prime region 371 (i.e., with devices) including metal pads 315 used in hybrid bonding and through-silicon vias (TSVs) 373 (i.e., for carrying signals in the active prime region 371 not the monoliths of the crackstops).

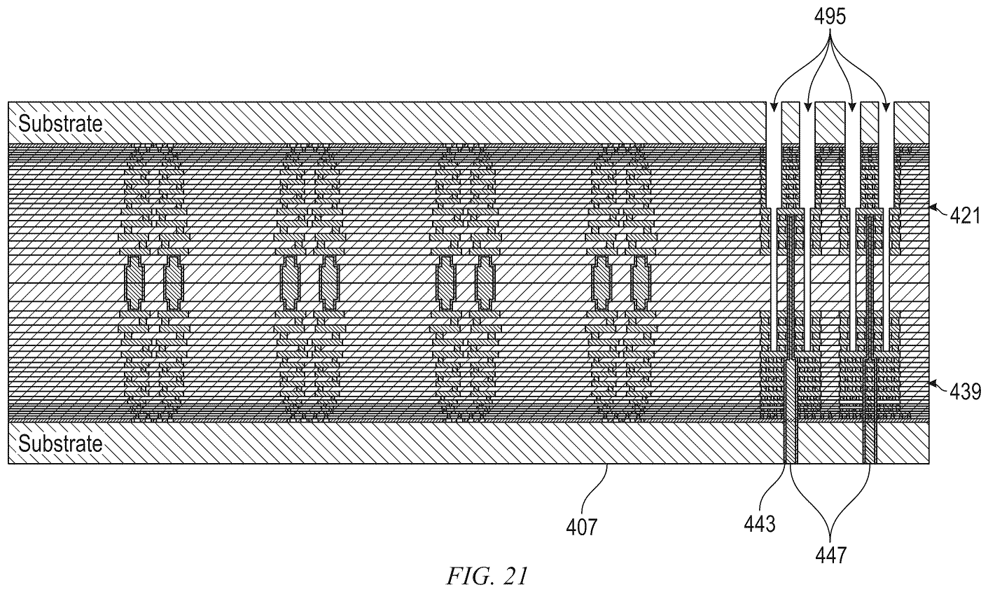

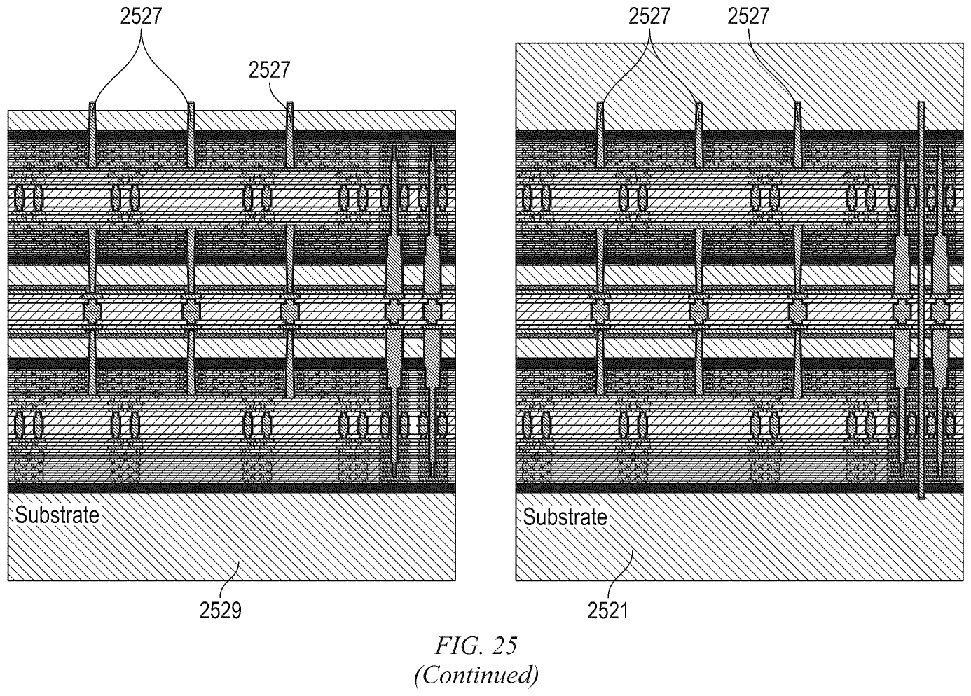

FIGS. 17-24 show an alternative exemplary process flow, according to an aspect of the invention. This aspect uses a somewhat similar build but the scaffolding is different (it has different gaps to allow for multiple TSVs of different lengths as it is built up to the final result in FIG. 24). A crack stop is provided on each wafer separately, a “flip” is carried out as discussed below, and a bidirectional copper (or other material) TSV monolith is the result. These bidirectional TSV monoliths breach across the interface and anchor into the joined builds, at the expense of requiring additional processing steps, but advantageously providing a robust bidirectional structural element that anchors from both ends. In particular, begin with the hybrid bonded structure 499 in FIG. 17. Structure 499 is similar to the structure shown in FIG. 2 in the active region, but does not include adhesion pads 317, 325 and has somewhat different scaffolding 421, 439.

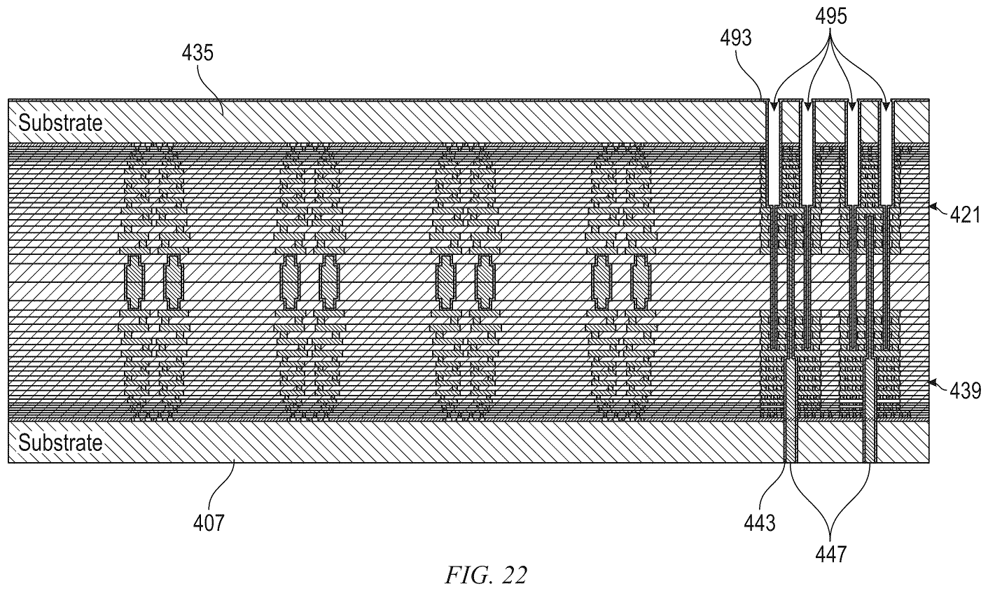

FIG. 18 shows the structure at the right-hand side of FIG. 17, after forming openings 441 for monoliths to be subsequently formed; for example, using etching such as reactive ion etching.

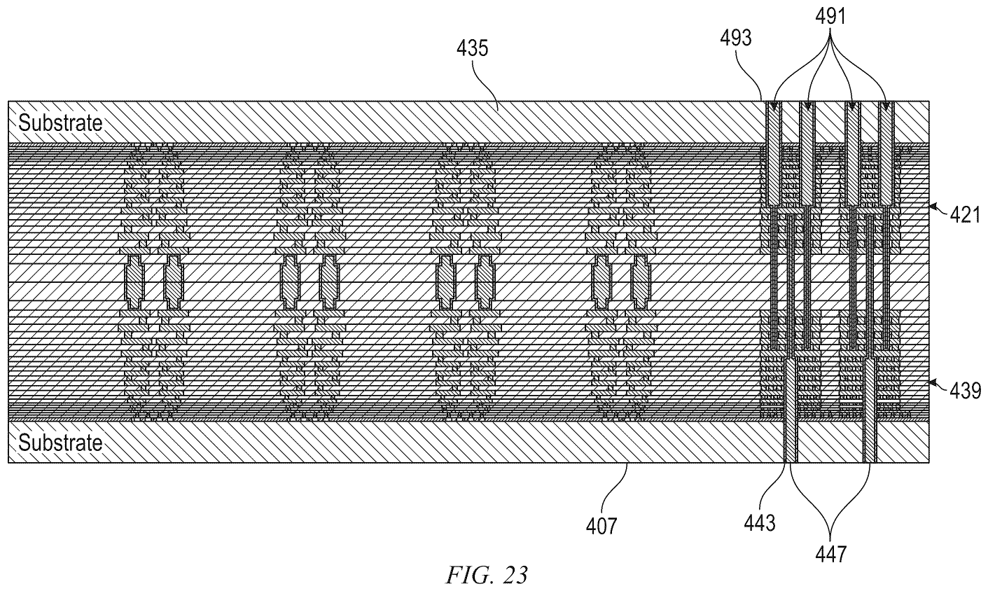

FIG. 19 shows the structure of FIG. 18 after depositing seed liner 443 in the openings 441 and on the top surface of the structure.

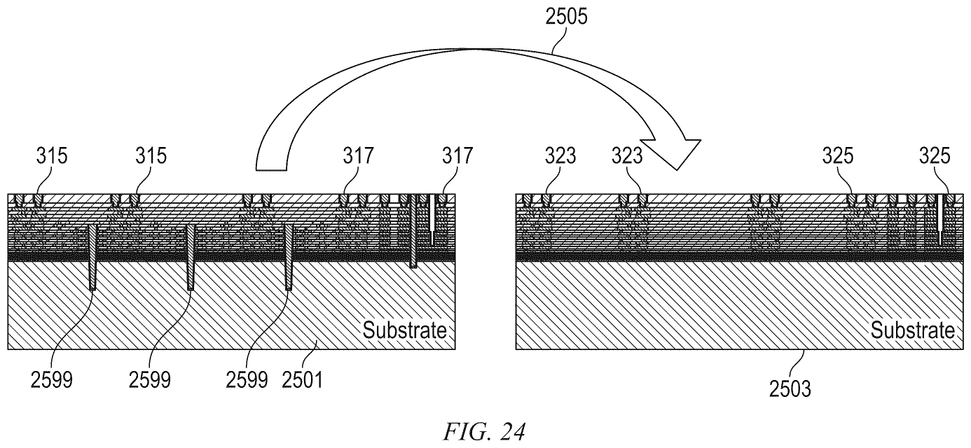

FIG. 20 shows the structure of FIG. 19 after metallizing with metal over the seed liner 443, filling the openings 441 (numbered in FIG. 4), and performing CMP to remove the metal and seed liner 443 from the outer surface of the substrate 407, leaving monoliths 447 in the openings 441 (numbered in FIG. 19).

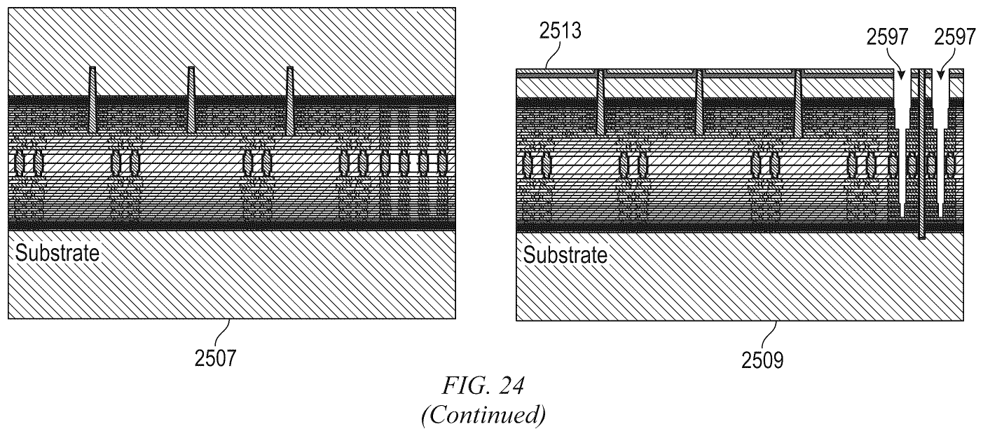

FIG. 21 shows the structure of FIG. 20 flipped 180 degrees about axis A-A in FIG. 20 so that it is oriented as shown in FIG. 21. FIG. 21 further shows forming openings 495 for monoliths to be subsequently formed; for example, using etching such as reactive ion etching.

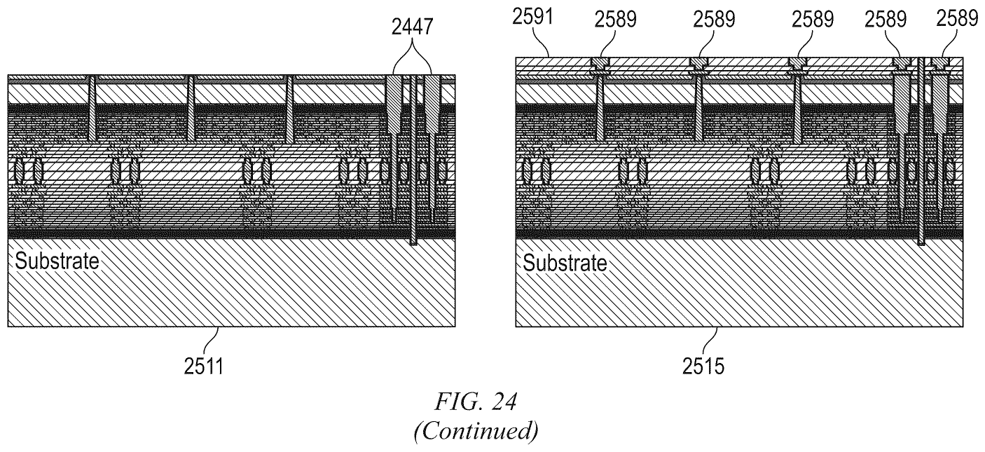

FIG. 22 shows the structure of FIG. 21 after depositing seed liner 493 in the openings 495 and on the top surface of the structure. Note substrate 435.

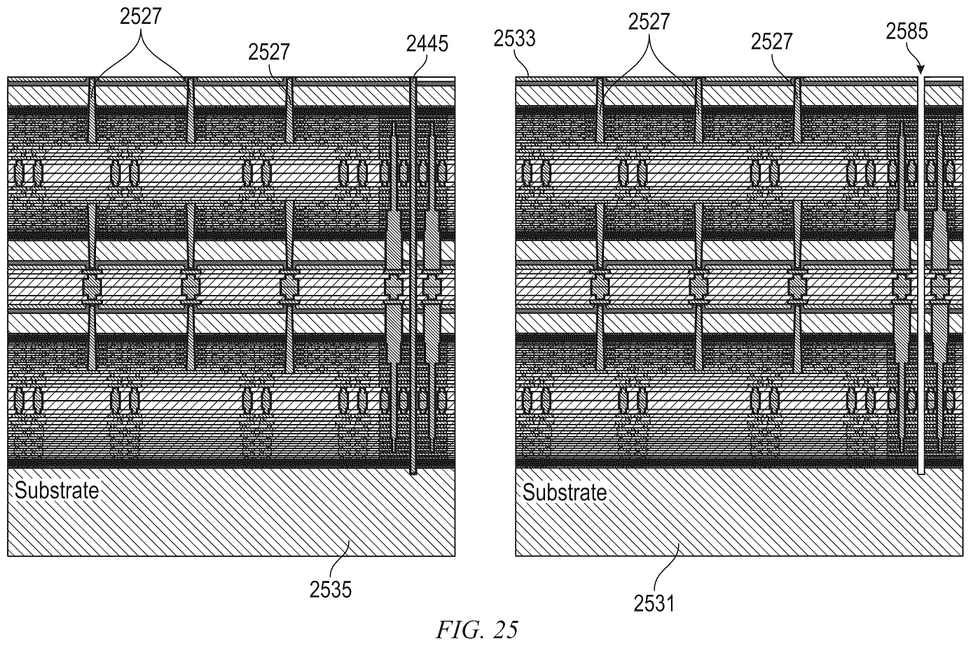

FIG. 23 shows the structure of FIG. 22 after metallizing with metal over the seed liner 493, filling the openings 495 (numbered in FIG. 22), and performing CMP to remove the metal and seed liner 493 from the outer surface of the substrate 435, leaving monoliths 491 in the openings 495 (numbered in FIG. 22).

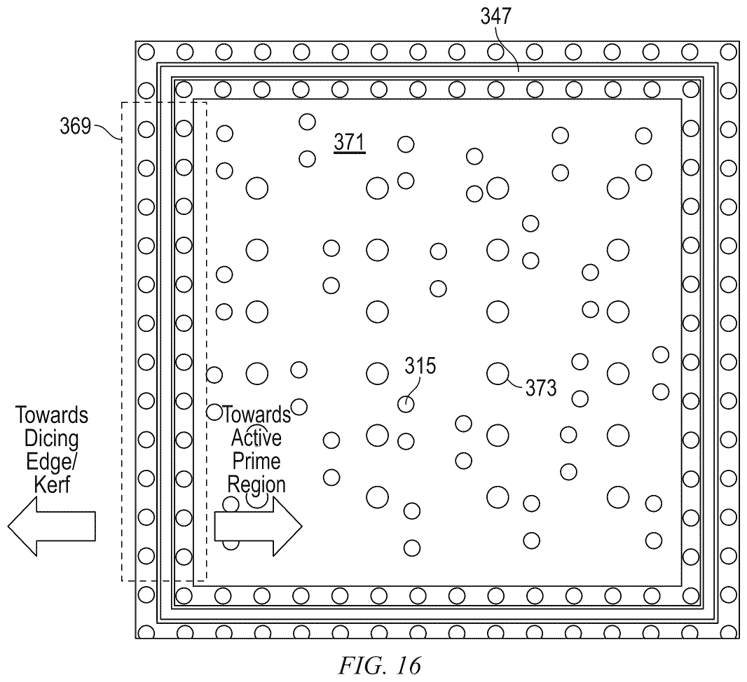

Refer now to FIGS. 24-26, which show another alternative exemplary process flow, according to another aspect of the invention. This aspect uses a stacking die assembly approach with additional columns (i.e., elements 317, 325 in FIG. 11 together with square metal portions 363 in FIG. 8 and the next continuous via 364 and the next horizontal metal plate/bar/line 362; basically, what is seen between 314, 327 in FIG. 11) and additional semiconductor builds. As best seen in FIG. 12, in one or more embodiments, the scaffolding is continuous and hermetic within a build. In the example of FIGS. 24-26, TSV monoliths (e.g., 2447) join adjacent builds and a “grand” TSV monolith 2445 joins all the builds. Build 2501 is analogous to build 301; note the metal pads 315 used in hybrid bonding, and scaffold structures (not numbered) with corresponding adhesion pads 317 that are similar to the metal pads 315. Also note the deep copper-filled TSVs 2599. Build 2503 is analogous to build 303; note the metal pads 323 used in hybrid bonding, and scaffold structures (not numbered) with corresponding adhesion pads 325 that are similar to the metal pads 323. In a step of the process flow illustrated with regard to builds 2501, 2503, first semiconductor build 2501 is flipped over and brought adjacent to second semiconductor build 2503 with pads 317 aligned with pads 325 and pads 315 aligned with pads 323. The flipping is suggested by arrow 2505 but in this particular example is not a simple 180 degree flip as the pads are aligned as described (other embodiments could have a mirrored layout such that only a simple 180 degree flip was needed). After the flipping, hybrid bonding is carried out to produce composite build 2507. Then, as seen at 2509, etch the substrate of the build 2501, apply insulation layer 2513, and etch TSVs 2597. Then, as seen at 2511, metallize the TSVs 2597 and carry out CMP to produce monoliths 2447; at 2515, add additional insulation in one or more layers 2591 and additional pads 2589.

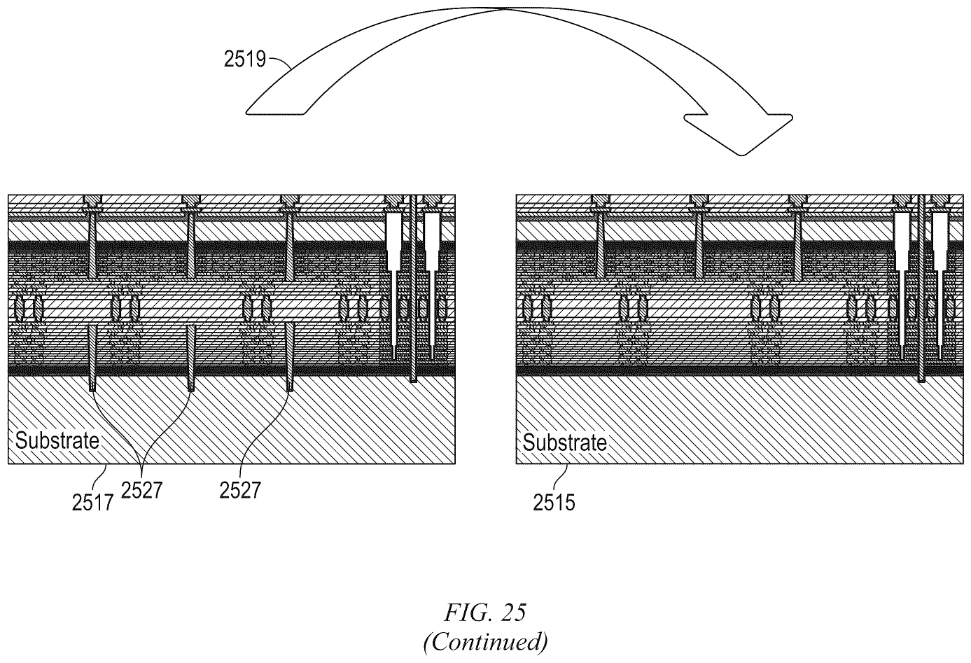

Note that the order in FIG. 24 generally proceeds from 2501 to 2515, while the order in FIG. 25 generally proceeds from 2515 to 2535. Composite build 2515 is shown in both FIG. 24 and FIG. 25. Composite build 2517 is flipped, as suggested by arrow 2519 to produce “grand” composite build 2521. Composite build 2517 is similar to composite build 2515 but has additional copper-filled TSVs 2527 and lateral wiring in both halves of the build, unlike composite build 2515. The flipping is suggested by arrow 2519 but in this particular example is not a simple 180 degree flip as the features are aligned as seen at 2521 (other embodiments could have a mirrored layout such that only a simple 180 degree flip was needed).

At 2529, etch the uppermost substrate of the “grand” composite build 2521 leaving ends of additional copper-filled TSVs 2527 exposed. At 2531, apply insulation layer 2533, and etch “grand” TSV 2585. At 2535, metallize the TSV 2585 and carry out CMP to produce “grand” monolith 2445.

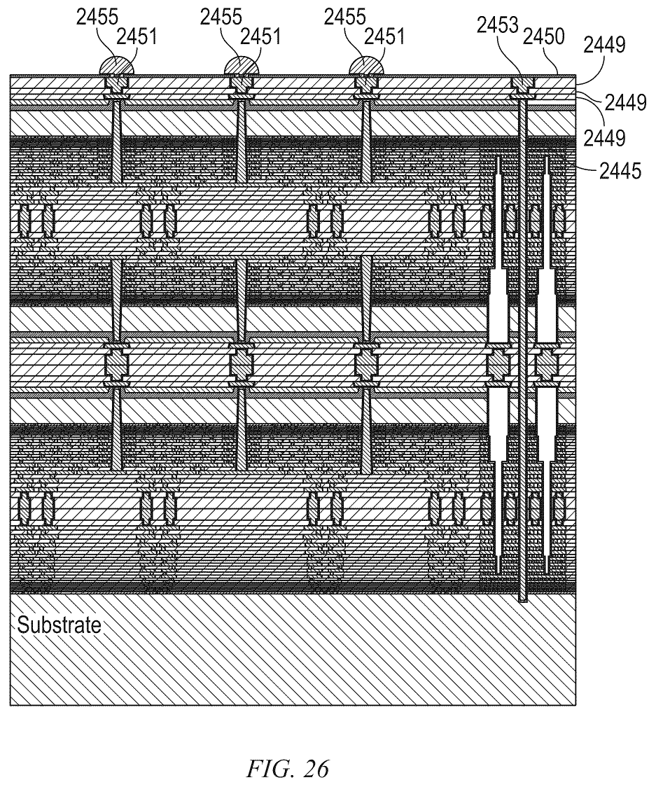

FIG. 26 shows the final structure after adding additional insulation layers 2449, passivation layer 2550, metal pads 2451, metal pad 2453 over “grand” monolith 2445, and solder bumps 2455. Given the teachings herein, the skilled artisan can select a suitable material for passivation layer 2550 (e.g., polyimide) for the solder bumps 2455.

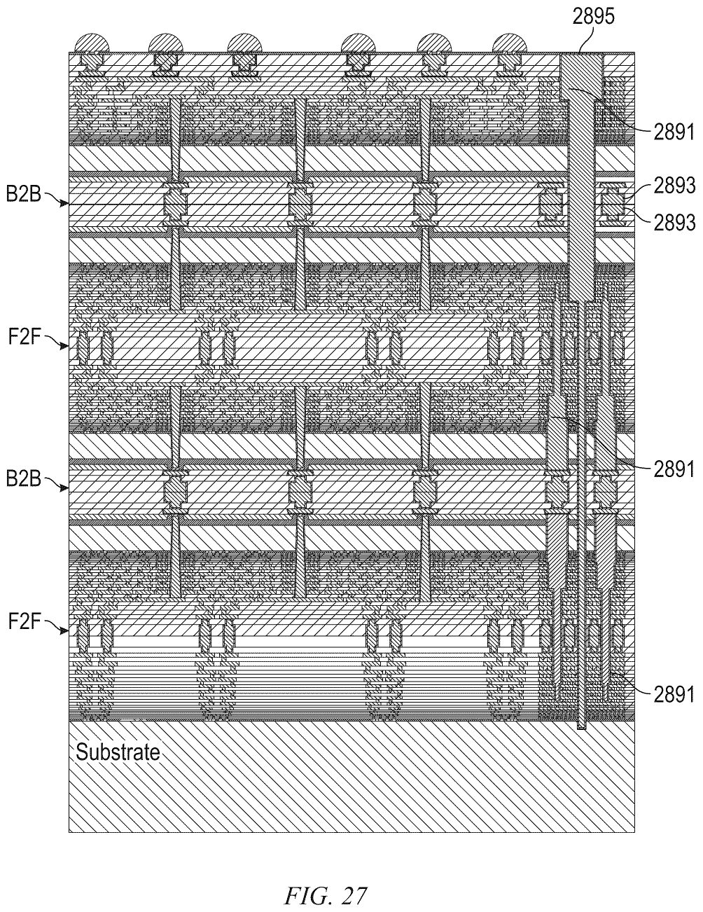

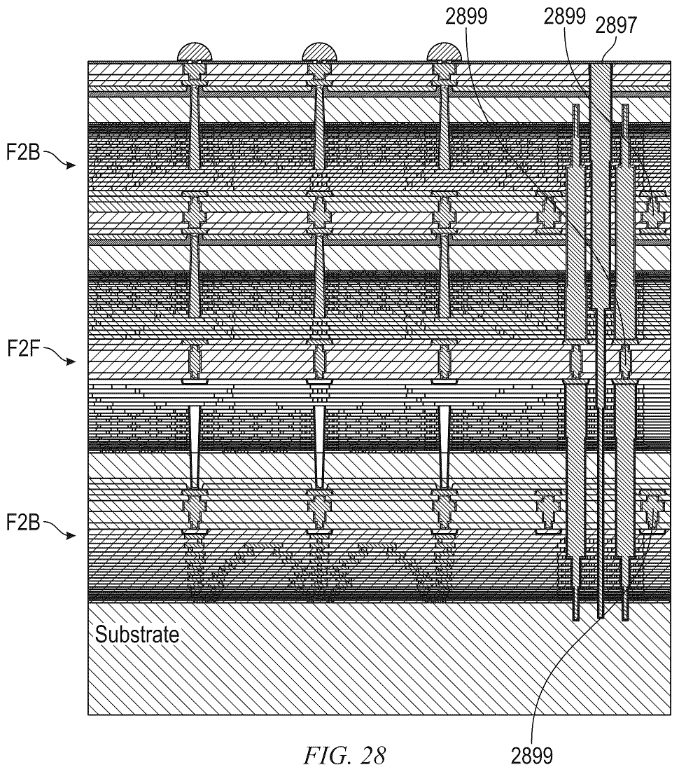

FIGS. 27 and 28 depict variant hybrid bonding stacking configurations, according to aspects of the invention. At 2891, note minute crackstop design changes in ‘scaffolding’ to allow for assembly (there are different gaps to allow for multiple TSVs of different lengths as it is built up to the final result in FIG. 28). Note the dummy joining pads 2893. At 2895 and 2897, note the 3D stack vertical supports or “grand” monoliths. Note B2B, F2F, and F2B joining (respectively, back-to-back, face-to-face, and face-to-back). At 2899 note hybrid bond pads integrated into scaffolding and on top of copper monolith walls.

It will accordingly be appreciated that one or more embodiments provide a mechanical crackstop barrier structure that has been built into BEOL dielectric layers and that is provided along with a semiconductor device build. The semiconductor device build includes a continuous seamless metal wall (e.g., continuous copper monolith 347) surrounding the periphery of the active prime device region 371, where each semiconductor build (wafer/die) has its own respective continuous crackstop and moisture barrier (MOB) 321, 339 “scaffolding” prior to joining/bonding, as seen, for example, in FIG. 12. That is to say, in one or more embodiments, within each build, the scaffolding before the join is hermetic not porous. In one or more embodiments, a seamless copper element such as 347, when integrated into the build, unifies the two adjoined structures into one piece. In one or more embodiments, this element is built into the BEOL layers 313, 331 of two respective semiconductor dies that have been joined together.

In some instances, the continuous seamless barrier (metal, copper, TEOS, or the like) bridges across a joining interface 349 between two joined semiconductor dies. In some cases, the continuous seamless metallic barrier aligns to and lands directly on and connects to a premade crackstop scaffolding (e.g., prebuilt). The continuous metal wall structure can, for example, be etched into and anchored into the base substrate of lower adjoined semiconductor dies (see 347A). This can be leveraged, for example, to create a guard ring.

In one or more embodiments, metal hybrid bond joining pads 317, 325 (in one or more embodiments, unlike the monolith, not continuous) are integrated into the crackstop architecture and are placed onto crackstop scaffolding or on copper monolith portions of a macroscopic crackstop architecture assembly; these hybrid joining pads supplement the mechanical strength/adhesion of joined parts and improve the quality of the hybrid bond of adjoined parts; they create a series of superior interconnect density joined spots around the periphery of the active prime region; and they create localized, finer pitch and denser mechanically robust joined spots along the periphery of adjoined semiconductor dies within a crackstop structure (increasing the strength of the region). During further processing steps, these joining structures can assist in alignment and prevent lateral shifting and vertical separation. Aspects of the invention can also be integrated into heat management and dissipation systems.

It is worth noting that one or more embodiments employ hybrid bonding/joining of two separate individual builds, with a copper monolith structure continuously surrounding the active region. In one or more embodiments, the active devices are not in the middle of the stack; they are at the base of each wafer and the crack stop is built in BEOL metallization layers outward of the wafer. See, e.g., FIG. 7.

It is worth noting that one or more embodiments employ hybrid bonding/joining combined with a copper monolith (‘TSV-Like’ structure) for connections between semiconductor builds, such as wafer-to-wafer, die-to-wafer, and/or die-to-die connections. One or more embodiments use copper monolith walls to bridge across adjoined/bonded semiconductor builds and discrete TSVs to make electrical connections across the builds. One or more embodiments integrate and unify two complete individual crackstops (i.e., in individual semiconductor builds that are joined using hybrid bonding) together with a solid copper (or other material) monolith). Furthermore, unlike prior art approaches using only discrete individual vias meant for signal/electrical transmission, one or more embodiments provide complete continuous walls to stop cracks and/or moisture ingress.

One or more embodiments advantageously incorporate multiple termination points in one via level of a crackstop as well as interlacing varying height via levels intricately and three dimensionally throughout a crackstop structure; for example, unlike prior art crackstop designs which do not have broken up interfaces. The layer thickness 361 can be typical dielectric BEOL thicknesses that can range, in a non-limiting example, from to 0.001 μm to 2 μm. Further, one or more embodiments advantageously reduce or eliminate direct line of sight seams that have been observed to be “unzipping” and resulting in failures in the prior art.

One or more embodiments thus advantageously provide hybrid bonding or joining of two semiconductor builds (e.g., wafer-to-wafer or die-to-wafer), creating a unified crackstop structure through the joining of prebuild individual elements using bonding pads, with inclusion of solid copper monolith (TSV-like) structures integrated into the joined parts. One or more embodiments advantageously allow for crack stopping and moisture blocking on two individual semiconductor builds prior to hybrid bonding/joining of the two builds together; then, once adjoined together, the individual crackstops of each build are unified together through the inclusion of a copper (or other) monolith wall that joins the two individual crackstop structures together, creating one continuous wall, and also providing/creating a crack stopping wall and moisture ingress protection at the joining interface.

Given the discussion thus far, it will be appreciated that, in general terms, an exemplary semiconductor structure includes an upper semiconductor build 301 having an upper crackstop structure 321 along an upper semiconductor build periphery (see FIG. 16). Also included are an upper semiconductor build insulator layer 314, and a plurality of upper semiconductor build electrical contact bonding pads 315 within the upper semiconductor build insulator layer. The upper semiconductor build crackstop structure includes first and second upper semiconductor build crackstop portions ending in first and second upper semiconductor build non electrical contact bonding pads 317 within the upper semiconductor build insulator layer.

The exemplary semiconductor structure further includes a lower semiconductor build 303 having a lower crackstop structure 339 along a lower semiconductor build periphery (see FIG. 16). Also included are a lower semiconductor build insulator layer 327, and a plurality of lower semiconductor build electrical contact bonding pads 323 within the lower semiconductor build insulator layer. The lower semiconductor build crackstop structure includes first and second lower semiconductor build crackstop portions ending in first and second lower semiconductor build non electrical contact bonding pads 325 within the lower semiconductor build insulator layer.

The upper and lower semiconductor builds are connected by a hybrid bond joining interface 349 including metal-to-metal bonding of the plurality of upper semiconductor build electrical contact bonding pads with the plurality of lower semiconductor build electrical contact bonding pads, metal-to-metal bonding of the first and second upper semiconductor build non electrical contact bonding pads with the first and second lower semiconductor build non electrical contact bonding pads, and dielectric bonding of the upper semiconductor build insulator layer with the lower semiconductor build insulator layer. The exemplary semiconductor structure further includes a continuous structural element 347 located between the first and second upper semiconductor build crackstop portions and the first and second lower semiconductor build crackstop portions, passing through the hybrid bond joining interface and sealing around the upper and lower semiconductor build peripheries.

In one or more embodiments, the upper semiconductor build further includes an upper semiconductor build substrate 307, an upper semiconductor build active device layer 309 located in a lower portion of the upper semiconductor build substrate, and an upper semiconductor build wiring layer 311 located below the upper semiconductor build active device layer and above the upper semiconductor build insulator layer. Furthermore, in one or more embodiments, the lower semiconductor build further includes a lower semiconductor build substrate 335, a lower semiconductor build active device layer 333 located in an upper portion of the lower semiconductor build substrate, and a lower semiconductor build wiring layer 331 located above the lower semiconductor build active device layer and below the lower semiconductor build insulator layer.

In some cases, the semiconductor structure further includes a plurality of upper semiconductor build active devices located in the upper semiconductor build active device layer and electrically coupled to the plurality of upper semiconductor build electrical contact bonding pads through the upper semiconductor build wiring layer; and a plurality of lower semiconductor build active devices located in the lower semiconductor build active device layer and electrically coupled to the plurality of lower semiconductor build electrical contact bonding pads through the lower semiconductor build wiring layer. Referring to FIG. 16, when viewed in plan, the plurality of upper semiconductor build active devices and the plurality of lower semiconductor build active devices are spaced inward of the upper and lower semiconductor build peripheries in an active prime region 371. In some such cases, the semiconductor structure further includes through-silicon vias (TSVs) 373 in the active prime region, configured to carry electrical signals.

As seen, for example, in FIG. 7, in some instances, the continuous structural element 347 is anchored into the upper semiconductor build substrate 307. As seen, for example, in FIG. 8, in some instances, the continuous structural element 347 is anchored into the lower semiconductor build substrate 335 as seen at 347A. Generally, elements 347 can be anchored in the top or bottom substrates or both.

In one or more embodiments, the continuous structural element, the upper crackstop structure, and the lower crackstop structure are electrically isolated from the plurality of upper semiconductor build active devices and the plurality of lower semiconductor build active devices.

Referring, for example, to FIG. 23, in some cases, the continuous structural element 491 extends from the upper semiconductor build substrate, and an additional continuous structural element 447 extends from the lower semiconductor build substrate.

The upper and lower semiconductor builds can each include, for example, at least one of a chip, die, wafer and interposer, or any combinations thereof.

As seen, for example, in FIG. 7, in some cases, the first and second upper semiconductor build crackstop portions and the first and second lower semiconductor build crackstop portions define a stepped region and the continuous structural element 347 is stepped corresponding to the stepped region defined by the first and second upper semiconductor build crackstop portions and the first and second lower semiconductor build crackstop portions.

Advantageously, in some instances, the first and second upper semiconductor build crackstop portions and the first and second lower semiconductor build crackstop portions are hermetic within the upper semiconductor build and the lower semiconductor build, respectively, as seen in FIG. 12. Referring to FIG. 7, in some such instances, the first and second lower semiconductor build crackstop portions and the first and second upper semiconductor build crackstop portions include horizontal metal portions 362 and continuous vias 364.

The continuous structural element can be a metal (copper is a non-limiting example), oxide (tetraethoxysilane is a non-limiting example), or other suitable material as discussed.

Referring, for example, to FIGS. 26-28, another exemplary semiconductor structure includes an upper composite semiconductor build and a lower composite semiconductor build. Each composite semiconductor build includes an upper semiconductor build and a lower semiconductor build configured similar to what has been described and fastened together by hybrid bonding and with a peripheral monolith. A “grand” continuous structural element, such as 2445, 2895, or 2897 passes through the upper and lower composite semiconductor builds and seals around an overall periphery of the final structure. The upper and lower composite semiconductor builds are in turn joined by a composite bond.

In another aspect, an exemplary method of forming a semiconductor structure includes providing upper and lower semiconductor builds as seen in FIG. 1; as seen in FIG. 2, connecting the upper and lower semiconductor builds by a hybrid bonding including metal-to-metal bonding of the plurality of upper semiconductor build electrical contact bonding pads with the plurality of lower semiconductor build electrical contact bonding pads, metal-to-metal bonding of the first and second upper semiconductor build non electrical contact bonding pads with the first and second lower semiconductor build non electrical contact bonding pads, and dielectric bonding of the upper semiconductor build insulator layer with the lower semiconductor build insulator layer. As seen in FIG. 3, the method further includes opening a trench between the first and second upper semiconductor build crackstop portions and the first and second lower semiconductor build crackstop portions, passing through a hybrid bond joining interface and around the upper and lower semiconductor build peripheries; and, as seen in FIGS. 4 and 5, depositing material in the trench to form a continuous structural element located between the first and second upper semiconductor build crackstop portions and the first and second lower semiconductor build crackstop portions, passing through the hybrid bond joining interface and sealing around the upper and lower semiconductor build peripheries.

Advantageously, the upper semiconductor build crackstop structure is hermetic within the upper semiconductor build and the lower semiconductor build crackstop structure is hermetic within the lower semiconductor build, and a further step includes protecting the upper semiconductor build and the lower semiconductor build from cracking and moisture damage prior to the connecting step, using the upper semiconductor build crackstop structure and the lower semiconductor build crackstop structure.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
an upper semiconductor build having an upper crackstop structure along an upper semiconductor build periphery, an upper semiconductor build insulator layer, and a plurality of upper semiconductor build electrical contact bonding pads within the upper semiconductor build insulator layer, wherein the upper semiconductor build crackstop structure includes first and second upper semiconductor build crackstop portions ending in first and second upper semiconductor build non electrical contact bonding pads within the upper semiconductor build insulator layer; and
a lower semiconductor build having a lower crackstop structure along a lower semiconductor build periphery, a lower semiconductor build insulator layer, and a plurality of lower semiconductor build electrical contact bonding pads within the lower semiconductor build insulator layer, wherein the lower semiconductor build crackstop structure includes first and second lower semiconductor build crackstop portions ending in first and second lower semiconductor build non electrical contact bonding pads within the lower semiconductor build insulator layer;
wherein the upper and lower semiconductor builds are connected by a hybrid bond joining interface including metal-to-metal bonding of the plurality of upper semiconductor build electrical contact bonding pads with the plurality of lower semiconductor build electrical contact bonding pads, metal-to-metal bonding of the first and second upper semiconductor build non electrical contact bonding pads with the first and second lower semiconductor build non electrical contact bonding pads, and dielectric bonding of the upper semiconductor build insulator layer with the lower semiconductor build insulator layer;
further comprising a continuous structural element located between the first and second upper semiconductor build crackstop portions and the first and second lower semiconductor build crackstop portions, passing through the hybrid bond joining interface and sealing around the upper and lower semiconductor build peripheries.

2. The semiconductor structure of claim 1, wherein:
the upper semiconductor build further comprises an upper semiconductor build substrate, an upper semiconductor build active device layer located in a lower portion of the upper semiconductor build substrate, and an upper semiconductor build wiring layer located below the upper semiconductor build active device layer and above the upper semiconductor build insulator layer; and
the lower semiconductor build further comprises a lower semiconductor build substrate, a lower semiconductor build active device layer located in an upper portion of the lower semiconductor build substrate, and a lower semiconductor build wiring layer located above the lower semiconductor build active device layer and below the lower semiconductor build insulator layer.

3. The semiconductor structure of claim 2, further comprising:
a plurality of upper semiconductor build active devices located in the upper semiconductor build active device layer and electrically coupled to the plurality of upper semiconductor build electrical contact bonding pads through the upper semiconductor build wiring layer; and
a plurality of lower semiconductor build active devices located in the lower semiconductor build active device layer and electrically coupled to the plurality of lower semiconductor build electrical contact bonding pads through the lower semiconductor build wiring layer;
wherein, when viewed in plan, the plurality of upper semiconductor build active devices and the plurality of lower semiconductor build active devices are spaced inward of the upper and lower semiconductor build peripheries in an active prime region.

4. The semiconductor structure of claim 3, further comprising through-silicon vias (TSVs) in the active prime region, configured to carry electrical signals.

5. The semiconductor structure of claim 3, wherein the continuous structural element is anchored into the upper semiconductor build substrate.

6. The semiconductor structure of claim 5, wherein the continuous structural element is anchored into the lower semiconductor build substrate.

7. The semiconductor structure of claim 6, wherein the continuous structural element, the upper crackstop structure, and the lower crackstop structure are electrically isolated from the plurality of upper semiconductor build active devices and the plurality of lower semiconductor build active devices.

8. The semiconductor structure of claim 2, wherein the continuous structural element extends from the upper semiconductor build substrate, further comprising an additional continuous structural element extending from the lower semiconductor build substrate.

9. The semiconductor structure of claim 1, wherein the upper semiconductor build includes at least one of a chip, die, wafer and interposer.

10. The semiconductor structure of claim 1, wherein said lower semiconductor build includes at least one of a chip, die, wafer and interposer.

11. The semiconductor structure of claim 1, wherein the first and second upper semiconductor build crackstop portions and the first and second lower semiconductor build crackstop portions define a stepped region and wherein the continuous structural element is stepped corresponding to the stepped region defined by the first and second upper semiconductor build crackstop portions and the first and second lower semiconductor build crackstop portions.

12. The semiconductor structure of claim 1, wherein the first and second upper semiconductor build crackstop portions and the first and second lower semiconductor build crackstop portions are hermetic within the upper semiconductor build and the lower semiconductor build, respectively.

13. The semiconductor structure of claim 12, wherein the first and second lower semiconductor build crackstop portions and the first and second upper semiconductor build crackstop portions comprise horizontal metal portions and continuous vias.

14. The semiconductor structure of claim 1, wherein the continuous structural element comprises metal.

15. The semiconductor structure of claim 14, wherein the continuous structural element comprises copper.

16. The semiconductor structure of claim 1, wherein the continuous structural element comprises oxide.

17. The semiconductor structure of claim 16, wherein the continuous structural element comprises tetraethoxysilane.

18. A semiconductor structure comprising:
an upper composite semiconductor build, comprising:
an upper composite semiconductor build upper semiconductor build having an upper composite semiconductor build upper crackstop structure along an upper composite semiconductor build upper semiconductor build periphery, an upper composite semiconductor build upper semiconductor build insulator layer, and a plurality of upper composite semiconductor build upper semiconductor build electrical contact bonding pads within the upper composite semiconductor build upper semiconductor build insulator layer, wherein the upper composite semiconductor build upper semiconductor build crackstop structure includes first and second upper composite semiconductor build upper semiconductor build crackstop portions ending in first and second upper composite semiconductor build upper semiconductor build non electrical contact bonding pads within the upper composite semiconductor build upper semiconductor build insulator layer; and
an upper composite semiconductor build lower semiconductor build having a an upper composite semiconductor build lower crackstop structure along an upper composite semiconductor build lower semiconductor build periphery, an upper composite semiconductor build lower semiconductor build insulator layer, and a plurality of upper composite semiconductor build lower semiconductor build electrical contact bonding pads within the upper composite semiconductor build lower semiconductor build insulator layer, wherein the upper composite semiconductor build lower semiconductor build crackstop structure includes first and second upper composite semiconductor build lower semiconductor build crackstop portions ending in first and second upper composite semiconductor build lower semiconductor build non electrical contact bonding pads within the upper composite semiconductor build lower semiconductor build insulator layer;
wherein the upper composite semiconductor build upper and lower semiconductor builds are connected by an upper composite semiconductor build hybrid bond joining interface including metal-to-metal bonding of the plurality of upper composite semiconductor build upper semiconductor build electrical contact bonding pads with the plurality of upper composite semiconductor build upper lower semiconductor build electrical contact bonding pads, metal-to-metal bonding of the upper composite semiconductor build first and second upper semiconductor build non electrical contact bonding pads with the upper composite semiconductor build first and second lower semiconductor build non electrical contact bonding pads, and dielectric bonding of the upper composite semiconductor build upper semiconductor build insulator layer with the upper composite semiconductor build lower semiconductor build insulator layer;
further comprising an upper composite semiconductor build continuous structural element located between the upper composite semiconductor build first and second upper semiconductor build crackstop portions and the upper composite semiconductor build first and second lower semiconductor build crackstop portions, passing through the upper composite semiconductor build hybrid bond joining interface and sealing around the upper composite semiconductor build upper and lower semiconductor build peripheries;
a lower composite semiconductor build, comprising:
a lower composite semiconductor build upper semiconductor build portion having a lower composite semiconductor build upper crackstop structure along a lower composite semiconductor build upper semiconductor build periphery, a lower composite semiconductor build upper semiconductor build insulator layer, and a plurality of lower composite semiconductor build upper semiconductor build electrical contact bonding pads within the lower composite semiconductor build upper semiconductor build insulator layer, wherein the lower composite semiconductor build upper semiconductor build crackstop structure includes first and second lower composite semiconductor build upper semiconductor build crackstop portions ending in first and second lower composite semiconductor build upper semiconductor build non electrical contact bonding pads within the lower composite semiconductor build upper semiconductor build insulator layer; and
a lower composite semiconductor build lower semiconductor build having a lower composite semiconductor build lower crackstop structure along a lower composite semiconductor build lower semiconductor build periphery, a lower composite semiconductor build lower semiconductor build insulator layer, and a plurality of lower composite semiconductor build lower semiconductor build electrical contact bonding pads within the lower composite semiconductor build lower semiconductor build insulator layer, wherein the lower composite semiconductor build lower semiconductor build crackstop structure includes first and second lower composite semiconductor build lower semiconductor build crackstop portions ending in first and second lower composite semiconductor build lower semiconductor build non electrical contact bonding pads within the lower composite semiconductor build lower semiconductor build insulator layer;
wherein the lower composite semiconductor build upper and lower semiconductor builds are connected by a lower composite semiconductor build hybrid bond joining interface including metal-to-metal bonding of the plurality of lower composite semiconductor build upper semiconductor build electrical contact bonding pads with the plurality of lower composite semiconductor build lower semiconductor build electrical contact bonding pads, metal-to-metal bonding of the lower composite semiconductor build first and second upper semiconductor build non electrical contact bonding pads with the lower composite semiconductor build first and second lower semiconductor build non electrical contact bonding pads, and dielectric bonding of the lower composite semiconductor build upper semiconductor build insulator layer with the lower composite semiconductor build lower semiconductor build insulator layer;
further comprising a lower composite semiconductor build continuous structural element located between the lower composite semiconductor build first and second upper semiconductor build crackstop portions and the lower composite semiconductor build first and second lower semiconductor build crackstop portions, passing through the lower composite semiconductor build hybrid bond joining interface and sealing around the lower composite semiconductor build upper and lower semiconductor build peripheries; and
a grand continuous structural element, passing through the upper and lower composite semiconductor builds and sealing around an overall periphery of the upper and lower composite semiconductor builds;
wherein the upper and lower composite semiconductor builds are in turn joined by a composite bond.

19. A method of forming a semiconductor structure, the method comprising:
providing:
an upper semiconductor build having an upper crackstop structure along an upper semiconductor build periphery, an upper semiconductor build insulator layer, and a plurality of upper semiconductor build electrical contact bonding pads within the upper semiconductor build insulator layer, wherein the upper semiconductor build crackstop structure includes first and second upper semiconductor build crackstop portions ending in first and second upper semiconductor build non electrical contact bonding pads within the upper semiconductor build insulator layer; and
a lower semiconductor build having a lower crackstop structure along a lower semiconductor build periphery, a lower semiconductor build insulator layer, and a plurality of lower semiconductor build electrical contact bonding pads within the lower semiconductor build insulator layer, wherein the lower semiconductor build crackstop structure includes first and second lower semiconductor build crackstop portions ending in first and second lower semiconductor build non electrical contact bonding pads within the lower semiconductor build insulator layer;
connecting the upper and lower semiconductor builds by a hybrid bonding including metal-to-metal bonding of the plurality of upper semiconductor build electrical contact bonding pads with the plurality of lower semiconductor build electrical contact bonding pads, metal-to-metal bonding of the first and second upper semiconductor build non electrical contact bonding pads with the first and second lower semiconductor build non electrical contact bonding pads, and dielectric bonding of the upper semiconductor build insulator layer with the lower semiconductor build insulator layer;
opening a trench between the first and second upper semiconductor build crackstop portions and the first and second lower semiconductor build crackstop portions, passing through a hybrid bond joining interface and around the upper and lower semiconductor build peripheries; and
depositing material in the trench to form a continuous structural element located between the first and second upper semiconductor build crackstop portions and the first and second lower semiconductor build crackstop portions, passing through the hybrid bond joining interface and sealing around the upper and lower semiconductor build peripheries.

20. The method of claim 19, wherein the upper semiconductor build crackstop structure is hermetic within the upper semiconductor build and the lower semiconductor build crackstop structure is hermetic within the lower semiconductor build, further comprising protecting the upper semiconductor build and the lower semiconductor build from cracking and moisture damage prior to the connecting step, using the upper semiconductor build crackstop structure and the lower semiconductor build crackstop structure.
